(19) United States
(12) Patent Application Publication
(10) Pub. No.: US 2024/0234606 A9
(43) Pub. Date: Jul. 11, 2024

(54) INCREASING THE DENSIFICATION OF SOLAR MODULES BY MAXIMIZED SUPERIMPOSED INTERCONNECTION

(71) Applicant: COMMISSARIAT À L'ÉNERGIE ATOMIQUE ET AUX ÉNERGIES ALTERNATIVES, Paris (FR)

(72) Inventors: Romain Soulas, Grenoble (FR); Bertrand Chambion, Grenoble (FR)

(21) Appl. No.: 18/489,940

(22) Filed: Oct. 19, 2023

(30) Foreign Application Priority Data
Oct. 20, 2022 (FR) 2210864

(51) Int. Cl. H01L 31/05; H01L 31/18

(52) U.S. Cl. CPC H01L 31/0504; H01L 31/1868

(57) ABSTRACT

A photovoltaic device comprising an assembly of several strings of photovoltaic cells, each of the strings being formed by a plurality of cells aligned in a first direction y, the strings being aligned in a second direction x forming a non-zero angle with the first direction and typically orthogonal or substantially orthogonal to the first direction, the assembly of cells including a first string laterally overlapped by a second chain of the plurality of strings, so that a peripheral portion of the second string covers a peripheral portion of the first string, the first string and the second string being electrically insulated via an insulating region interposed between the respective peripheral portions of the first string and of the second string.

### CROSS-REFERENCE TO RELATED APPLICATIONS

This application claims priority from French Patent Application No. 2210864 filed on Oct. 20, 2022. The content of this application is incorporated herein by reference in its entirety.

### TECHNICAL FIELD AND PRIOR ART

The present application relates to the field of photovoltaic module making and provides an improved assembly of several strings of interconnected solar or photovoltaic cells and in particular crystalline silicon based photovoltaic cells.

A conventional solar module is typically formed by several juxtaposed strings of cells commonly called “strings”.

A string of cells includes a series of several cells electrically connected together and generally aligned in a given first direction. The connection between cells of the same string may be made via conductive strips or wires which extend in the first direction and successively come into contact with at least one upper or lower face of each cell.

In general, a module includes, in a direction orthogonal to the first direction, several strings of cells parallel to each other.

To improve the surface power of a photovoltaic module, one could attempt to increase the efficiency of the cells and/or densify the active surface of the modules.

It is known to achieve a densification of the modules by reducing the inter-cell spaces within the same string of cells, and even by making the cells of the same string overlap over each other.

For example, the document US2021202784 describes a particular way for assembling the cells of a string of cells wherein the cells overlap each other according to a “shingle”-type arrangement commonly called “shingle” or, except for the end cells of a string, each cell overlaps a preceding neighboring cell and is overlapped by a following neighboring cell of the series of cells forming the string. A structure of the so-called “paving” type, replicates a similar arrangement but with conductive strips or wires to make the connection between the cells.

Another arrangement type provides, except for the end cells of one string, for each cell either being overlapped by its preceding and following neighboring cells, or overlapping its preceding and following neighboring cells of the series of cells.

The problem of finding a new means for improving the surface power of a photovoltaic module arises.

### DISCLOSURE OF THE INVENTION

In particular, the present invention relates to a photovoltaic device comprising an assembly of several strings of cells, this assembly including at least one first string laterally overlapped by a second string of cells, the first string and the second string being electrically insulated from each other via an insulating region interposed between a peripheral portion of the first string and a peripheral portion of the second string of cells.

Such an arrangement allows obtaining an improved surface density. Moreover, electrical continuity between adjacent cells is achieved while avoiding short-circuits.

Such an arrangement allows for equal cell number and cell size compared to a module with a conventional arrangement, having a reduced encapsulation.

According to one embodiment, the present invention relates to a photovoltaic device comprising an assembly of several strings of cells, each of the strings being formed by a plurality of cells aligned in a first direction y, the strings being aligned in a second direction x forming a non-zero angle with the first direction and typically orthogonal or substantially orthogonal to the first direction, the assembly of cells including at least one first string laterally overlapped by a second string of the plurality of strings, so that a peripheral portion of the second string covers a peripheral portion of the first string, the first string and the second string being electrically insulated via an insulating region interposed between the respective peripheral portions of the first string and of the second string.

By “substantially parallel”, it should herein be understood it forms an angle smaller than 5° and by “substantially orthogonal”, it should herein be understood it forms an angle larger than 85°.

Advantageously, the second string of cells is juxtaposed and laterally overlaps or is laterally overlapped by a third string of cells.

The first string of cells may be coated with one or more first conductive track(s) which extend(s) parallel or substantially parallel to the first direction y, the second string of cells being coated with one or more second conductive track(s) which extend(s) parallel or substantially parallel to the first direction y, the first conductive track(s) being connected to the second conductive track(s) via an interconnection conductive area arranged on a first side of the assembly at a first end of the first string and at a first end of the second string.

According to a particular embodiment, the second string of cells is juxtaposed and laterally overlaps or is laterally overlapped by a third string of cells, the third string of cells being coated with one or more third conductive track(s) which extend(s) in particular parallel or substantially parallel to the first direction, the third string of cells being juxtaposed and laterally overlapping or being laterally overlapped by a fourth string of cells, the fourth string of cells being coated with one or more fourth conductive track(s) which extend(s) in particular parallel or substantially parallel to the first direction, the first string, the second string, the third string, the fourth string having a first end located on the first side of the assembly and a second end located on a second side of the assembly opposite to the first side of the assembly, the third conductive track(s) being connected to the fourth conductive track(s) via another interconnection conductive area arranged on the second side of the assembly.

Advantageously, the first end and the second end of the first string are offset respectively with respect to the first end and the second end of the second string.

According to an advantageous embodiment, the cells are of the pseudo-square type, with beveled edges, the cells of the first string overlapping so that a longitudinal edge of a first cell is arranged opposite the beveled edges of a second cell next to the first cell.

Advantageously, the insulating region is made of or comprises a material having adhesive properties.

According to a possible implementation, the insulating region may be formed of a material transparent to photons at a wavelength comprised between 200 nm and 1,200 nm, in particular between 400 and 800 nm.

According to one embodiment, the insulating region may be formed of a thermoplastic or thermosetting material.

According to another embodiment, the insulating region may be formed of an inorganic material.

Advantageously, the insulating region may be formed of a material having a dielectric strength higher than the voltage maximum value (Voc) present between two juxtaposed strings of cells. In particular, the insulating region may be formed of a material having a dielectric strength comprised between 15 and 30 V.

According to another aspect, the present invention relates to a method for manufacturing a photovoltaic device as defined before.

According to one embodiment, the method comprises the following steps:
assembling a set of photovoltaic cells so as to form at least the first string of cells and of passivating opposite peripheral portions of the cells of the set of cells and located along lateral edges of the cells, to form the insulating region, then,
assembling the first string of cells and the second string of cells by carrying out the lateral overlap of the second string over the first string of cells, the second string of cells being arranged in contact with the insulating region.

The passivation of the peripheral portions may be carried out after a step of assembling cells to form the first string of cells.

Advantageously, the method may comprise forming conductive tracks over the first string and at least one interconnection conductive area with conductive tracks of a second string of cells adjacent to the first string, the interconnection conductive area being made after said passivation.

### BRIEF DESCRIPTION OF THE DRAWINGS

The present invention will be better understood based on the following description and the appended drawings wherein:

FIG. 1 is intended to illustrate a string of solar cells arranged according to a tiling or paving type configuration.

FIG. 2 is intended to illustrate an arrangement according to the invention of parallel strings of solar cells with a lateral overlap between adjacent strings of solar cells.

FIG. 3 is intended to illustrate a variant of lateral overlapping between adjacent strings of solar cells.

FIG. 4 is intended to illustrate an intermediate insulating region between adjacent strings of solar cells which laterally overlap.

FIG. 5 is intended to illustrate a first type of arrangement of laterally overlapping strings of solar cells.

FIG. 6 is intended to illustrate another type of arrangement of laterally overlapping strings of solar cells.

FIGS. 7A, 7B and 7C are intended to illustrate a first embodiment of the passivation of lateral edges of the laterally overlapping strings of cells.

FIGS. 8A, 8B and 8C are intended to illustrate an embodiment of the passivation of lateral edges of the strings of cells wherein the passivation is carried out after assembly of the cells into strings of cells.

FIGS. 9A, 9B and 9C are intended to illustrate an embodiment of the passivation of lateral edges of the strings of cells wherein the passivation is carried out before assembly of the cells into strings of cells.

FIG. 10 is intended to illustrate a particular example of arrangement of adjacent strings of cells with ends of adjacent strings offset from each other.

Identical, similar or equivalent portions of the different figures bear the same reference numerals so as to facilitate passage from one figure to another.

The different portion shown in the figures are not necessarily plotted according to a uniform scale, to make the figures more readable.

### DETAILED DISCLOSURE OF PARTICULAR EMBODIMENTS

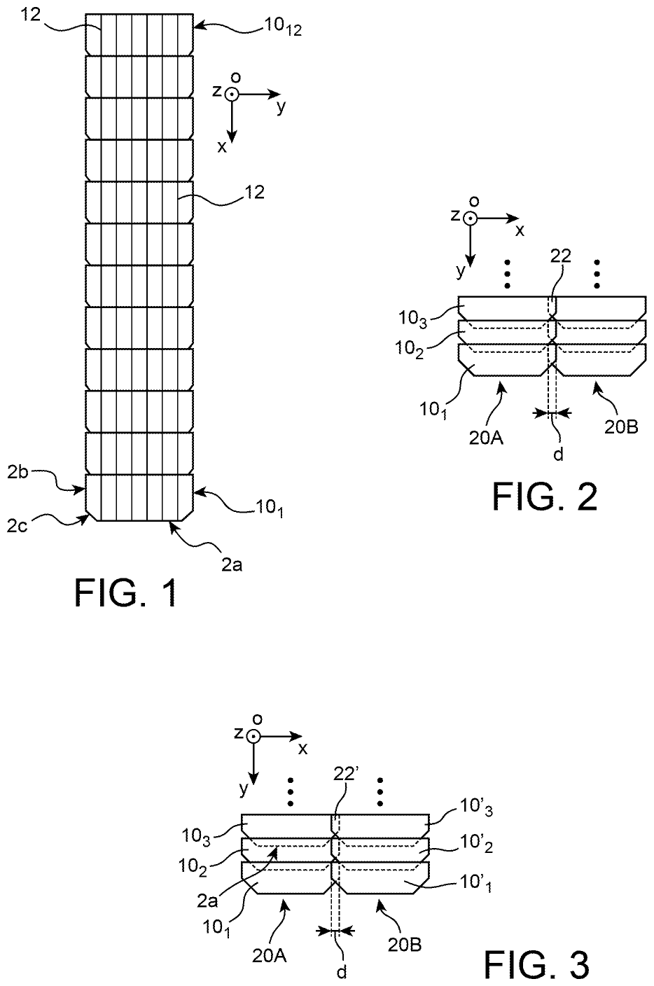

An example of arrangement of a string 20A of solar cells 10₁, . . . , 10₁₂ that could be integrated into a photovoltaic module as implemented according to the invention is illustrated in FIG. 1.

In this example, the cells 10₁, . . . , 10₁₂ are of the pseudo-square or pseudo-rectangular type with beveled edges 2c that at oblique with respect to so-called “lateral” 2b and “longitudinal” 2a edges of the cell.

The lateral edges 2b are hollow which extend in a first direction, typically parallel or substantially parallel to that of an axis y (of an orthogonal reference frame [O; ° x; ° y; ° z] in FIG. 1) which herein corresponds to the direction in which the string 20A of cells 10₁, . . . , 10₁₂ extends.

The longitudinal edges 2a are herein those which extend in a second direction in which the strings of the module are distributed. The second direction is typically substantially orthogonal or orthogonal to the first direction, in other words parallel or substantially parallel to that of an axis x of the orthogonal reference frame [O; ° x; ° y; ° z].

The arrangement of the cells within the string 20A is herein such that from one end to another of the string of cells 10₁, . . . , 10₁₂, each cell overlaps or is overlapped by an adjacent cell of the series of cells 10₁, . . . , 10₁₂ forming the string. Thus, each cell is provided with a longitudinal edge 2a, which is covered by a cell portion that is next to it or located at the end of a portion that projects opposite the neighboring cell.

In the illustrated example, each cell 10₁, . . . , 10₁₂ extends in particular in a plane distinct from that in which the other cells 10₁, . . . , 10₁₂ respectively extend. Nonetheless, a different arrangement within the string 20A may be provided for. Thus, alternatively, the cells 10₁, . . . , 10₁₂ may have an arrangement in which the successive cells are arranged alternately in a first plane or in a second plane distinct from the first plane and parallel to the latter.

The cells 10₁, . . . , 10₁₂ are herein electrically connected by means of one or more conductive element(s) 12 which extend over the cells in the form of conductive strips or conductive wires, for example a silver-based metallic material, and from one end to another of the strip of cells 10₁, . . . , 10₁₂. Thus, the cells 10₁, . . . , 10₁₂ may have an arrangement and a connection according to a tiling-like (“paving”) configuration.

In the illustrated particular embodiment, the conductive elements 12 extend over a so-called “upper” face of the string of cells herein formed by all of the exposed front faces of the cells 10₁, . . . , 10₁₂.

The wires 12 may undergo crushing along the assembly of strings of cells 10₁, . . . , 10₁₂, in order to limit the mechanical stress but also to increase the adhesion of these to the cells 10₁, . . . , 10₁₂. The conductive elements 12 may be fastened by gluing, or soldering, or using a solder paste. Alternatively, these conductive elements 12 may be arranged over, or integrated into, a polymer material layer that is affixed on the cells 10₁, . . . , 10₁₂.

To form a photovoltaic module, the string 20A of cells 10₁, . . . , 10₁₂ that has just been described is intended to be assembled to other strings of cells, which are typically connected together in series.

Alternatively to the illustrated configuration example, the cells 10₁, . . . , 10₁₂ may have a shingle configuration with a connection between neighboring cells so that an interconnection conductive area is located between an upper face of a first cell and a lower face of a second cell next to the first cell.

The assembly between strings of cells herein has the particularity of providing for a lateral overlap between neighboring strings of cells.

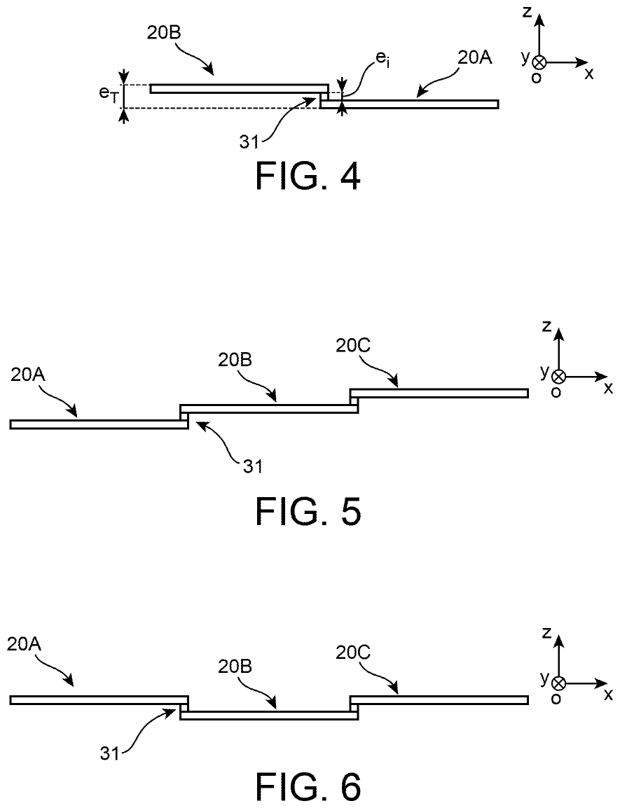

Thus, in FIG. 2, the lateral overlap between strings of cells is such that a portion 22 of a first string 20A of cells 10₁, 10₂, 10₃ is arranged over a portion (not referenced in this figure) of a neighboring second string 20B in other words adjacent to the first one. The lateral overlap may be such that a projection d comprised for example between 0.01 mm and 5 mm, in particular between 0.5 and 1 mm of a string of cells 20A over the neighboring string 20B may be provided for.

In order not to lose or to limit a loss of active area, the value of this projection d (also called “overlap”) may advantageously be close to that of a trimming (not shown) typically provided for at the rear face of the cells. Such a trimming may correspond to an inactive peripheral area in contrast with the active and central area generally coated with a transparent conductive material such as ITO (standing for “Indium Tin Oxide”).

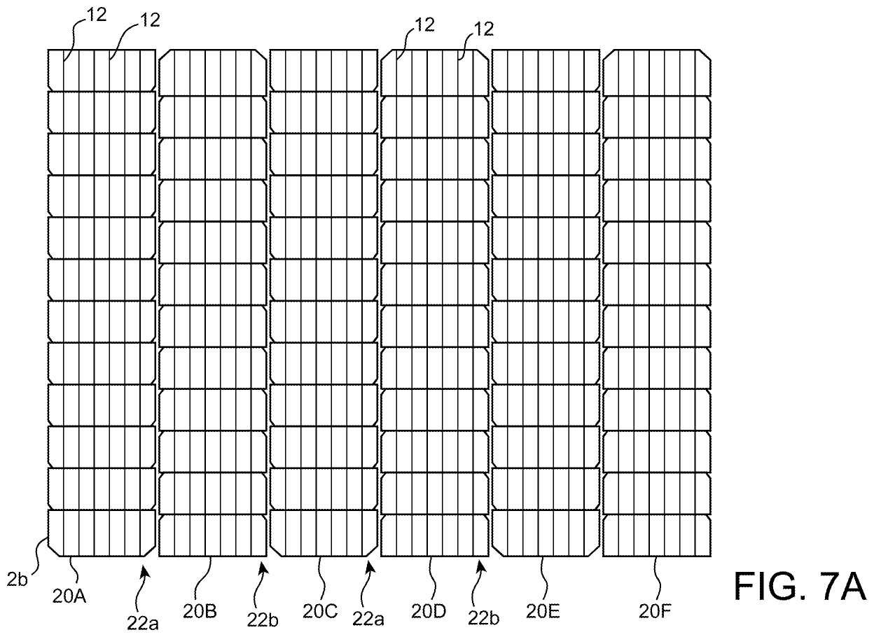

In FIG. 3, a lateral overlap is also provided for between the strings 20A, 20B of cells, but this time so that a portion 22′ of the second string 20B of cells 10′₁, 10′₂, 10′₃ covers apportion (not referenced in this figure) of the string 20A.

Rather than a mere juxtaposition with strings of cells spaced apart from each other, such a lateral overlap contributes to a densification of the photovoltaic module, including for example between 2 and 20 parallel strings of cells.

To enable such a lateral overlap of a string of cells over a neighboring string while avoiding setting these adjacent strings of cells in short-circuit, an intermediate region 31 made of an electrically-insulating material 32 is provided for. Thus, this region 31 so-called insulating region 31 is arranged at least in the overlap area and over a portion of the faces of the cells of the string 20A which is overlapped and covered by the cells of the neighboring string 20B.

Preferably, the material of the insulating region 31 is provided with an optical transparency to photons for a wavelength comprised between 200 nm and 1,200 nm.

The insulating region 31 may be in the form of a layer or a strip, for example made of a thermoplastic, or thermosetting, material, or an insulating film. Advantageously, the insulating material 32 may be a polymer, for example poly(ethylene terephtalate) (PET).

The insulating material 32 may possibly be coated with an adhesive material or have, itself, adhesive properties. A PET layer with an acrylic adhesive like for example a layer commercialized under the name of Tesa® 4129 may for example be used. A layer 32 of an insulating material, in particular a polymer, and having adhesive properties over one of its faces or over both of its faces may be used.

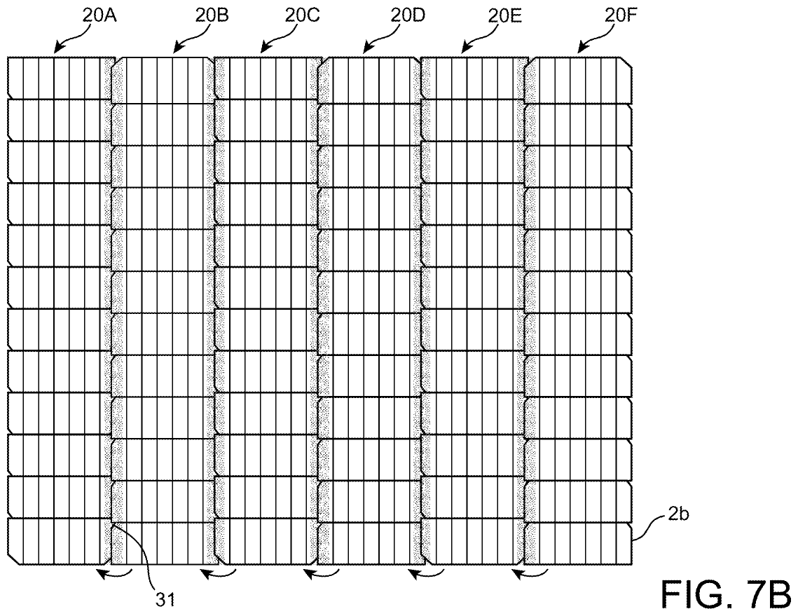

The insulating region 31 is provided, in terms of composition and thickness, so as to have a good dielectric strength and in particular a dielectric strength higher than a ratio of a maximum voltage difference at two adjacent strings 20A, 20B of cells and of the thickness e_{T} of the device (dimension measured parallel to the axis z in FIG. 4).

In the particular case of a region 31 made of an insulating material 32 for example a polymer and with a dielectric rigidity in the range of 15 kV/mm, a maximum voltage in the range of 17 V between two adjacent strings 20A, 20B (corresponding for example to 12 cells per string and a voltage of 0.7 V per cell) a thickness eᵢ of at least 2 μm of the insulating polymer is provided for in order to ensure the function. Advantageously, the region 31 made of an insulating material 32 may be provided with a minimum voltage to be held, comprised between 15 V and 30 V.

Also preferably, the material of the insulating region 31 is selected so that it preserves its dielectric strength properties up to a temperature, for example in the range of 200° C., to which it might be subjected throughout the process of the manufacturing the module.

The distribution of the insulating region 31 is not limited to that one illustrated in FIG. 4. It may possibly extend beyond the interlayer area between the cells of distinct strings.

Besides the electrical insulation between adjacent strings of cells, the insulating region 31 may contribute to the mechanical strength of the assembly between the adjacent strings of cells. Thus, this insulating region 31 may participate to holding neighboring strings of cells secured together in particular during the manufacture of the module. In particular, during a lamination step commonly used and during which the assembly is subjected to a pressure, the insulating region 31 allows avoiding a movement of the strings of cells relative to each other.

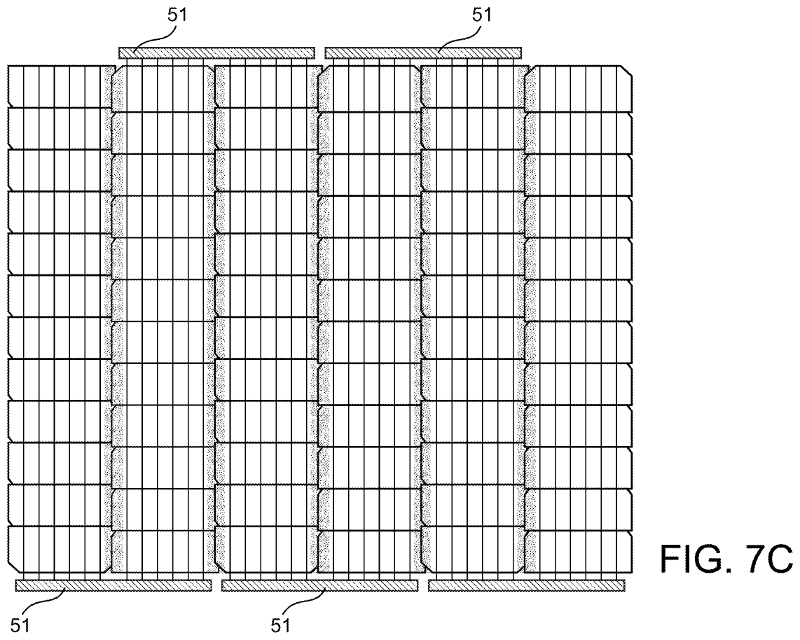

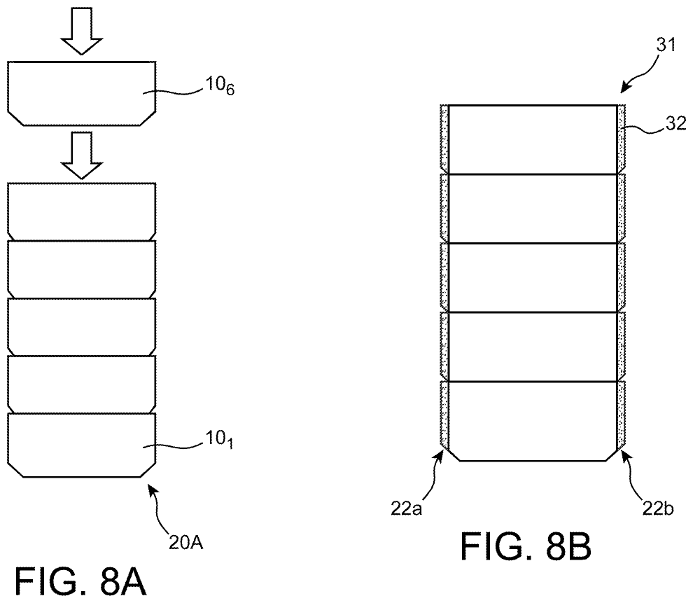

Like for the cells within the same string, an arrangement of the strings of cells as in FIG. 5 or an arrangement like in FIG. 6 may be provided for.

In the first arrangement type, each string 20A or 20B or 20C is located in a plane distinct from those in which the other strings 20A, 20B, 20C respectively extend.

In the second arrangement type, the strings 20A, 20B, 20C are located alternately in a first plane and in a second plane distinct from the first plane.

The assembly of the strings of cells with a lateral overlap may be integrated in a conventional module manufacturing method while limiting the addition of more steps.

An additional step of passivating lateral portions of strings of cells over which a neighboring string is intended to rest may be provided for.

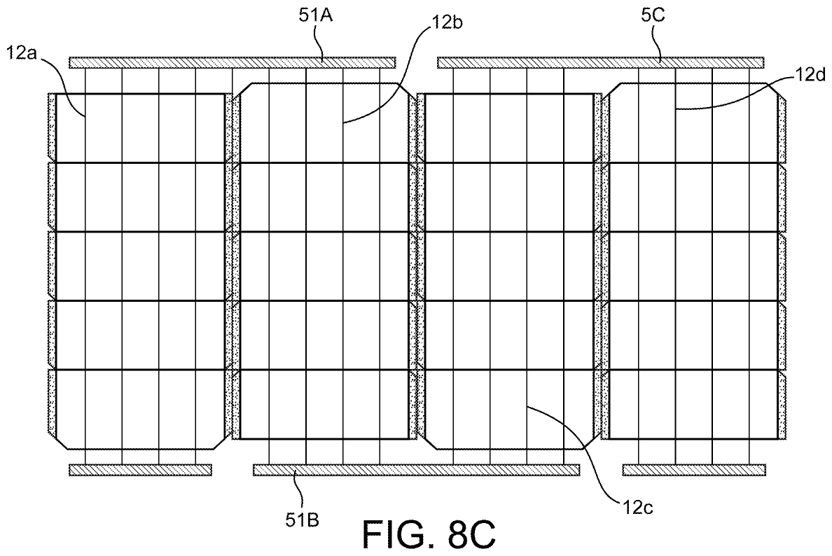

Thus, in the embodiment illustrated in FIGS. 7A-7B, several strings 20A, 20B, 20C, 20D, 20E, 20F of cells are formed at first (FIG. 7A).

Each of the strings of cells is then provided with conductive elements such as conductive strips or wires 12 which extend in the main direction of the string (in other words the direction in which all of the cells of this string extend).

Afterwards, peripheral portions 22a, 22b of the cells located along their respective lateral edges 2b are coated with an insulating material 32 (FIG. 7B), to form the insulating region(s) 31.

A localized deposition of an insulating material directly over the string of cells in particular using a liquid-phase deposition technique or an inkjet printing, or liquid spray, or soaking, or stamping technique may be performed.

This passivation step may be carried out by means of a piece of equipment that already exists and/or is adapted to carry out other steps. A machine for making strings (“stringer”) or a machine for setting the strings, or a piece of equipment dedicated to making of the strings as well as assembly thereof may be modified and adapted to carry out such a step.

A particular technique for depositing the insulating material uses an ink containing a polymer material, preferably thermosetting, and for example based on Epoxy, or silicone, or polyurethane, or acrylic, or acrylate. Baking or cross-linking the liquid-deposited polymer(s) may then be carried out in a conventional manner by UV irradiation, or by heating with an adapted variable thermal profile, or directly with air.

Afterwards (FIG. 7C), connection areas, in particular interconnection areas 51 between adjacent cells, are formed at the ends of the strings of cells 20A, 20B, 20C, 20D, 20E on either side of the assembly.

The implementation of the lateral overlap allows reducing the amount of materials used in particular to carry out the encapsulation. The method can be integrated in a production line of photovoltaic modules without inducing an additional cost.

Alternatively, the passivation of the edges of chains may be carried out before forming the parallel conductive lines 12 formed along each string.

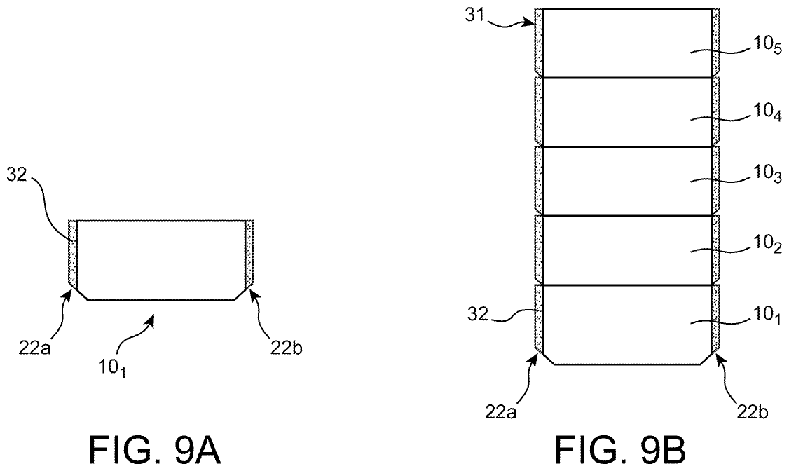

Thus, in the exemplary manufacturing method illustrated in FIGS. 8A-8C, an assembly of cells into a string 20A of cells 10₁, . . . , 10₆ is carried out at first (FIG. 8A).

Then (FIG. 8B), an insulating region 31 is formed over the peripheral portions 22a, 22b at the lateral edges 2a of the cells of this string 20A.

Then, the assembly of this string 20A of cells with an adjacent string or a set of strings already assembled is performed, by carrying out a lateral overlap as described before.

Thus, a first string 20A of cells is coated with first conductive tracks 12a whereas the second string 20B of cells is coated with second conductive tracks 12b, the first conductive strings 12a being connected to the second conductive tracks 12b via an interconnection electrically-conductive area 51A arranged on a first side of the assembly at a first end of said first string 20A and of the second string 20B. The second string 20B of cells which is laterally overlapped or laterally overlaps a third string 20C of cells is coated with third conductive tracks 12c. The third string of cells is laterally overlapped or overlaps a fourth string 20D of cells, itself coated with fourth conductive tracks 12d. The third conductive tracks 12c being connected to the fourth conductive tracks 12d via another interconnection electrically-conductive area 51B arranged on a second side of the assembly opposite to the first side of the assembly where the interconnection area 51A of the first and second conductive tracks 12a, 12b is located.

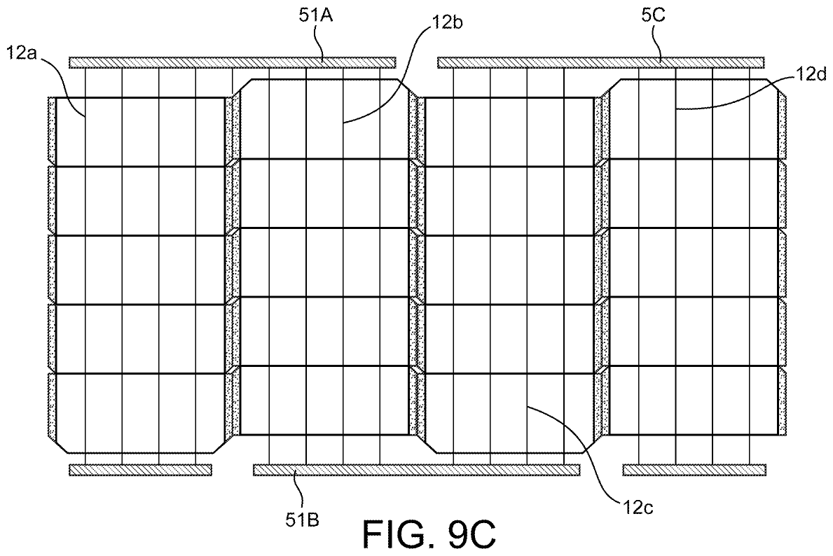

According to another variant illustrated in FIGS. 9A-9C, a passivation area made of an insulating material 32 is first made (FIG. 9A) over peripheral portions 22a, 22b of at least one face, in particular the front face, of a solar cell 10₁.

Afterwards (FIG. 9B), this cell 10₁ is assembled with other cells in order to form a string 20A of cells, each of the cells 10₁, 10₂, 10₃, 10₄, 10₅ of this string being preferably coated with passivation areas made of an insulating material 32 over peripheral portions 22a, 22b.

The string of cells thus formed is provided with lateral portions with an insulating region 31 herein formed by all of the individual passivation areas of the cells of the string.

Then, the assembly between the strings of cells is carried out by performing a lateral overlap as described before.

Afterwards (FIG. 9C), the cells within each string and interconnection areas 51A, 51B of neighboring strings are connected together.

In any of the previously-described embodiments, the set of strings of cells is distributed such that the strings of cells typically have the same length and are arranged parallel to each other, consequently with their respective ends aligned. This is the case for example in FIG. 7C.

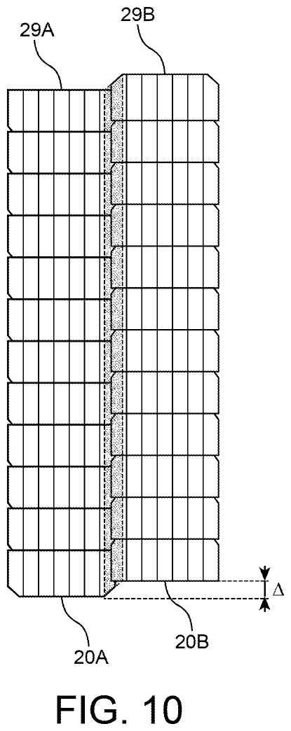

Alternatively, like in FIG. 10, it is possible to provide for an offset A between the respective ends 29A, 29B of adjacent strings 20A, 20B of cells. Such an offset may be considered in particular when an overlap between the cells within the same string is provided for. In this case, the formation of intersection points of four distinct cells and having, at these singular points, four thicknesses of cells, are avoided. According to a particular embodiment of such a variant, a staggered distribution of the ends of the strings of cells may be provided for.

An offset, typically between 1 mm and a length in the range of half the size of the cell, may be provided for.

The above-described particular arrangement of strings that laterally overlap has been illustrated before in combination with a particular arrangement of the ells within a string of cells wherein the cells overlap each other in pairs, for example according to a paving-type or shingle-type arrangement.

Nonetheless, the adjacent strings with a lateral overlap may, alternatively, be strings wherein a conventional arrangement of cells is provided for. Thus, the lateral overlap of the strings of cells may also be implemented with a series of cells arranged one after another without no overlapping of the cells within the same string.

The lateral overlap of the strings of cells described hereinabove applies to different types of cells, for example also to cells of the interdigitated back contact type (IBC, standing for “Interdigitated Back Contact”).

The lateral overlap of the strings also applies to different technologies for manufacturing strings of cells, for example also to that one implementing a SWCT™-type particular interconnection.

A solar module with lateral overlapping of the strings of cells as described before finds various applications. For example, it may be integrated to a solar farm or to a roof terrace, to a solar vehicle, and possibly find application in the space field.

1. A photovoltaic device comprising an assembly of several strings of photovoltaic cells, each of said strings being formed by a plurality of photovoltaic cells aligned in a first direction, said strings being aligned in a second direction forming a non-zero angle with the first direction and typically orthogonal or substantially orthogonal to the first direction, said assembly including at least one first string laterally overlapped by a second string of said plurality of strings, so that a peripheral portion of said second string covers a peripheral portion of said first string, said first string and said second string being electrically insulated via an insulating region interposed between said respective peripheral portions of the first string and of the second string.

2. The photovoltaic device according to claim 1, wherein said second string of cells is juxtaposed and laterally overlaps or is laterally overlapped by a third string of cells.

3. The photovoltaic device according to claim 1, wherein said first string of cells is coated with one or more first conductive track(s) which extend(s) parallel or substantially parallel to the first direction, said second string of cells being coated with one or more second conductive track(s) which extend(s) parallel or substantially parallel to the first direction, the first conductive track(s) being connected to the second conductive track(s) via an interconnection electrically-conductive area arranged on a first side of the assembly at a first end of said first string and at a first end of said second string.

4. The photovoltaic device according to claim 3, wherein the second string of cells is juxtaposed and laterally overlaps or is laterally overlapped by a third string of cells, the third string of cells being coated with one or more third conductive track(s) which extend(s) in particular parallel or substantially parallel to the first direction, the third string of cells being juxtaposed and laterally overlapping or being laterally overlapped by a fourth string of cells, said fourth string of cells being coated with one or more fourth conductive track(s) which extend(s) in particular parallel or substantially parallel to the first direction, the first string, the second string, the third string, the fourth string having a first end located on the first side of the assembly and a second end located on a second side of the assembly opposite to said first side of the assembly, the third conductive track(s) being electrically connected to said fourth conductive track(s) via another interconnection electrically-conductive area arranged on said second side of the assembly.

5. The photovoltaic device according to claim 3, wherein the first end and the second end of the first string are offset respectively with respect to the first end and the second end of the second string.

6. The photovoltaic device according to claim 1, wherein said cells are of the pseudo-square type, with beveled edges, the cells of the first string overlapping so that a longitudinal edge of a first cell is arranged opposite said beveled edges of a second cell next to said first cell.

7. The photovoltaic device according to claim 1, wherein the insulating region is made of or comprises a material having adhesive properties.

8. The photovoltaic device according to claim 1, the insulating region being formed of a material transparent to photons at a wavelength comprised between 200 nm and 1,200 nm, advantageously between 400 and 800 nm.

9. The photovoltaic device according to claim 1, the insulating region (31) being formed of a thermoplastic or thermosetting material.

10. The photovoltaic device according to claim 1, the insulating region being formed of a material having a dielectric strength comprised between 15 and 30 V.

11. A method for manufacturing a photovoltaic device according to claim 1, comprising the following steps:
assembling a set of photovoltaic cells so as to form at least the first string of cells and of passivating opposite peripheral portions of the cells of said set of cells and located along lateral edges of said cells, to form said insulating region, then
assembling the first string of cells and the second string of cells by carrying out the lateral overlap of the second string over the first string of cells, the second string of cells being arranged in contact with said insulating region.

12. The method according to claim 11, wherein the passivation of the peripheral portions is carried out after a step of assembling cells to form said first string of cells.

13. The method according to claim 11, further comprising forming conductive tracks over said first string and at least one interconnection conductive area with conductive tracks of a second string of cells adjacent to the first string, said interconnection conductive area being made after said passivation.
